(19) United States
(12) Patent Application Publication
(10) Pub. No.: US 2020/0411527 A1
(43) Pub. Date: Dec. 31, 2020

(54) MEMORY STRUCTURE

(71) Applicant: NANYA TECHNOLOGY CORPORATION, New Taipei City (TW)

(72) Inventor: SHENG-HUI YANG, TAOYUAN CITY (TW)

(21) Appl. No.: 16/454,963

(22) Filed: Jun. 27, 2019

(51) Int. Cl. H01L 27/108; H01L 29/78; H01L 29/08; H01L 49/02; H01L 29/45; H01L 29/165; H01L 29/66; H01L 21/306; H01L 21/308; H01L 21/02

(52) U.S. Cl. CPC H01L 27/10826; H01L 29/1608; H01L 27/10811; H01L 29/0847; H01L 28/90; H01L 29/45; H01L 29/165; H01L 29/6656; H01L 21/30604; H01L 21/3083; H01L 29/66636; H01L 21/02532; H01L 21/02529; H01L 29/66795; H01L 27/10879; H01L 27/10855; H01L 27/10888; H01L 29/7848

(57) ABSTRACT

One aspect of the present disclosure provides a memory structure, including a substrate having at least one fin; a gate stack across the at least one fin; a first strained layer disposed at a first side of the gate; a second strained layer disposed at a second side of the gate; a bit line contact structure electrically connected to the first strained layer; and a capacitor contact electrically connected to the second strained layer. The memory structure further includes a capacitor electrically connected to the second strained layer via the capacitor contact. The memory structure further includes a bit line electrically connected to the first strained layer via the bit line contact structure.

### TECHNICAL FIELD

The present disclosure relates to a memory structure and a method for preparing the same, and more particularly, to a memory structure integrating the strained layer and a method for preparing the same.

### DISCUSSION OF THE BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, a three dimensional transistor, such as a fin-type field-effect transistor (FinFET), has been introduced to replace a planar transistor. Although existing FinFET devices and methods of forming FinFET devices have been generally adequate for their intended purposes, they have not been entirely satisfactory in all respects.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a memory structure, including a substrate having at least one fin; a gate stack across the at least one fin; a first strained layer disposed at a first side of the gate; a second strained layer disposed at a second side of the gate; a bit line contact structure electrically connected to the first strained layer; and a capacitor contact electrically connected to the second strained layer

In some embodiments, the first strained layer has a lower part below the substrate and an upper part above the substrate, and a sidewall of the lower part of the strained layer has a smoothly curved profile.

In some embodiments, the memory structure further comprises a bit line electrically connected to the first strained layer via the bit line contact structure.

In some embodiments, the bit line contact structure comprises a first contact, a second contact, and a landing pad between the first contact and the second contact.

In some embodiments, the memory structure further comprises a capacitor electrically connected to the second strained layer via the capacitor contact.

In some embodiments, the memory structure further comprises a bottom electrode, an upper electrode and a dielectric layer between the bottom electrode and the upper electrode.

In some embodiments, the gate stack comprises a gate and a dielectric layer between the at least one fin and the gate.

In some embodiments, the memory structure further comprises silicide layers on the first strained layer and second strained layer.

In some embodiments, the first strained layer includes silicon germanium

In some embodiments, the first strained layer includes silicon carbon or silicon phosphate.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 is a cross-sectional view of intermediate stages in the formation of a memory structure in accordance with some embodiments of the present disclosure.

FIG. 2 is a cross-sectional view of intermediate stages following FIG. 1 in the formation of a memory structure in accordance with some embodiments of the present disclosure.

FIG. 3 is a cross-sectional view of intermediate stages following FIG. 2 in the formation of the memory structure in accordance with some embodiments of the present disclosure.

FIG. 4 is a cross-sectional view of intermediate stages following FIG. 3 in the formation of the memory structure in accordance with some embodiments of the present disclosure.

FIG. 5 is a cross-sectional view of intermediate stages following FIG. 4 in the formation of the memory structure in accordance with some embodiments of the present disclosure.

FIG. 6 is a cross-sectional view of a memory structure in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

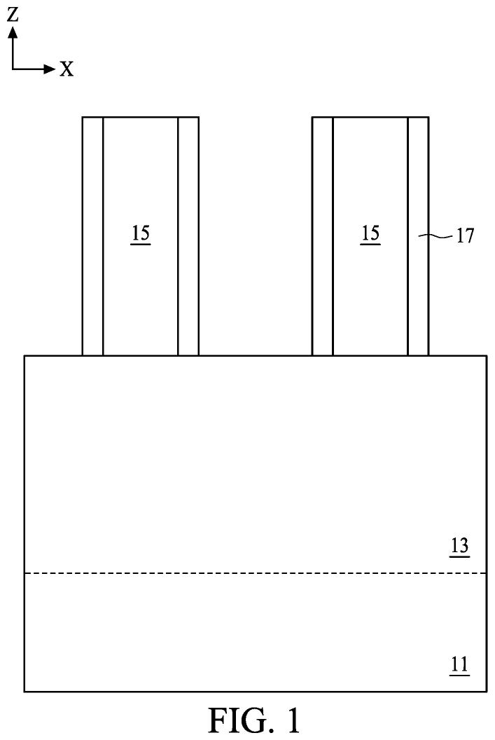

FIGS. 1 through 6 are cross-sectional views of intermediate stages in the formation of a memory structure 100 in accordance with some embodiments of the present disclosure.

Referring to FIG. 1, a substrate 11 with one or more fins 13 is provided. In some embodiments, the substrate 11 includes a silicon-containing substrate, a silicon-on-insulator (SOI) substrate, or a substrate formed of other suitable semiconductor materials. Depending on the requirements of design, the substrate 11 may be a P-type substrate or an N-type substrate and may have doped regions therein. The doped regions may be configured for an N-type FinFET device or a P-type FinFET device. In some embodiments, the substrate 11 has an isolation layer formed thereon. Specifically, the isolation layer covers lower portions of the fins 13 and exposes upper portions of the fins 13. In some embodiments, the isolation layer is a shallow trench isolation (STI) structure.

In some embodiments, the substrate 11 has at least two patterns 15 formed thereon. In some embodiments, the patterns 15 extend in a direction (Z direction) different from (e.g., perpendicular to) the extending direction (X direction) of the fins 13. In some embodiments, the patterns 15 include silicon oxide, silicon oxynitride or a combination thereof, the patterns 15 include a silicon-containing material, such as polysilicon, amorphous silicon or a combination thereof. In some embodiments, the patterns 15 include SiN, SiC, SiCN, SION, SiCON or a combination thereof. In some embodiments, the method of forming the patterns 15 includes forming a layer on the substrate 11 and patterning the layer with photolithography and etching processes.

In some embodiments, the substrate 11 further has spacers 17 formed on sidewalls of the patterns 15. In some embodiments, the spacers 17 have a dielectric constant less than about 10, or even less than about 5. In some embodiments, the spacers 17 include a nitrogen-containing dielectric material, a carbon-containing dielectric material or both. In some embodiments, the spacers 17 include SiN, SiCN, SiOCN, SiC, SiOC, SiON, a combination thereof or the like. In some embodiments, the method of forming the spacers 17 includes forming a spacer material layer on the substrate 11, and partially removing the spacer material layer by an anisotropic etching process.

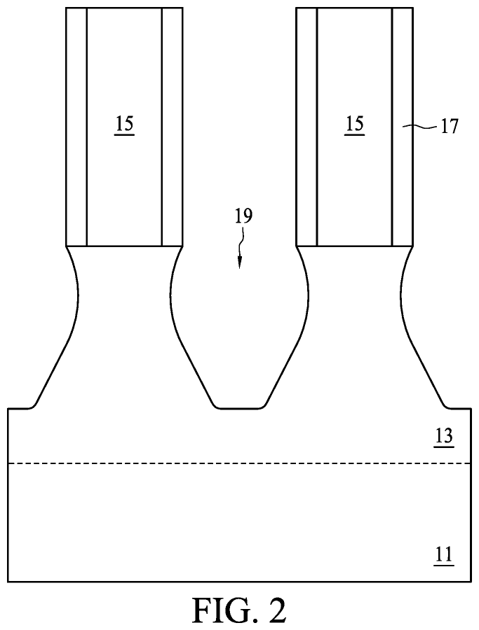

FIG. 2 is a cross-sectional view of intermediate stages following FIG. 1 in the formation of the memory structure 100 in accordance with some embodiments of the present disclosure, recesses 19 are formed in the substrate 11 between the patterns 15 by etching processes. In some embodiments, the etching processes include a first etching step and a second etching step, by using the patterns 15 and the spacers 17 as self-aligned etching masks. In some embodiments, the first etching step includes performing an anisotropic etching process, such as a dry etching process. In some embodiments, the recesses 19 are formed with a U-shaped profile, a cup-like profile or a bowl-like shape. In some embodiments, the top edge of the recesses 19 is aligned with the sidewalls of the adjacent spacers 17. In some embodiments, a second etching step is performed to deepen and widen the recess 19. In some embodiments, the second etching step includes performing an isotropic etching process, such as a wet etching process.

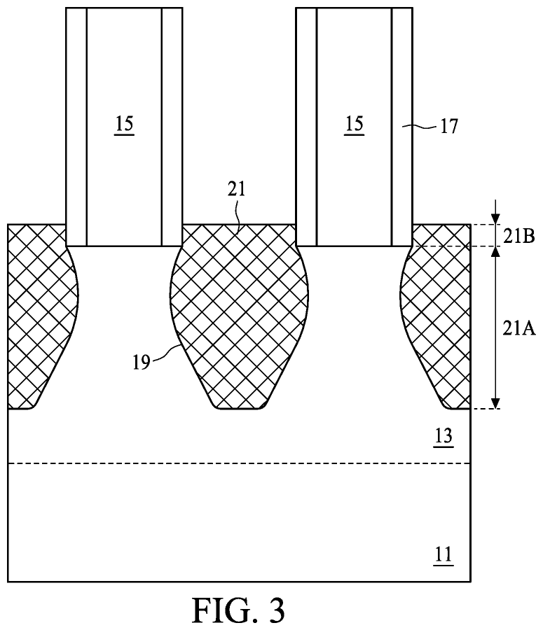

FIG. 3 is a cross-sectional view of intermediate stages following FIG. 2 in the formation of the memory structure 100 in accordance with some embodiments of the present disclosure, strained layers 21 are formed in the recesses 19. In some embodiments, two strained layers 21 are formed beside each of the patterns 15, and one of the strained layers 21 is between the adjacent patterns 15. In some embodiments, the strained layer 21 has a lower part 21A in the substrate 11 and an upper part 21B above the substrate 11, and a sidewall of the lower part 21A of the strained layer 21 has a smoothly curved profile. In some embodiments, the strained layers 21 include silicon germanium (SiGe) for a P-type FinFET device. In alternative embodiments, the strained layers 21 include silicon carbon (SiC), silicon phosphate (SiP), SiCP or a SiC/SiP multi-layer structure for an N-type FinFET device. In some embodiments, the strained layers 21 may be optionally implanted with a P-type dopant or an N-type dopant as needed. In some embodiments, the method of forming the strained layers 21 includes growing epitaxy layers from the recesses 19. In some embodiments, the strained layers 21 are formed within the recesses 19 and extend upwardly along the sidewalls of the corresponding spacers 17. In some embodiments, the tops of the strained layers 21 are above the surface of the substrate 11. In alternative embodiments, the tops of the strained layers 21 are substantially coplanar with the surface of the substrate 11. In some embodiments, the strained layers 21 can be referred to as “source/drain regions”.

In some embodiments, the adjacent strained layers 21 at the same side are separated from each other. In alternative embodiments, the adjacent strained layers 21 at the same side are connected with each other. In some embodiments, following the formation of the strained layers 21, silicide layers are formed by siliciding the top portions of the strained layers 21.

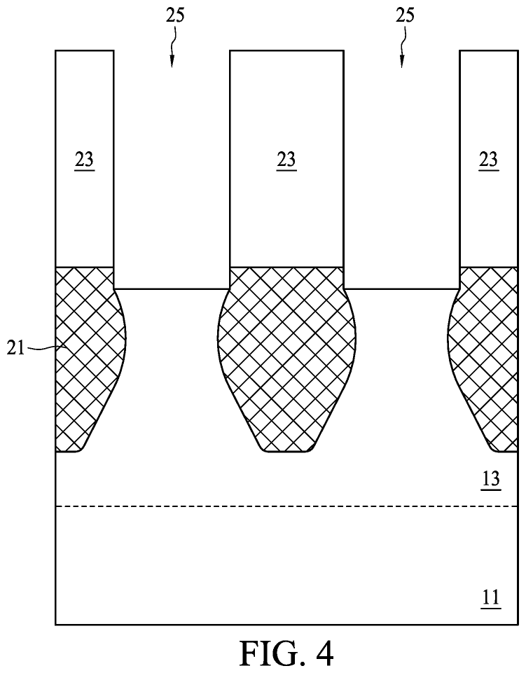

FIG. 4 is a cross-sectional view of intermediate stages following FIG. 3 in the formation of the memory structure 100, a dielectric layer 23 is formed aside the patterns 15 and over the strained layers 21; then, the patterns 15 and the spacers 17 are removed to form gate trenches 25 in the dielectric layer 23. In some embodiments, the dielectric layer 23 includes nitride such as silicon nitride, oxide such as silicon oxide, phosphosilicate glass (PSG), borosilicate glass (BSG), boron-doped phosphosilicate glass (BPSG), a combination thereof or the like. In some embodiments, the top surface of the dielectric layer 23 is substantially level with the top surfaces of the patterns 15. The dielectric layer 23 may be filled until its top surface is higher than the top surfaces of the patterns 15 by a suitable fabrication technique such as spin-coating, CVD, flowable CVD, PECVD, ALD, a combination or the like. A planarization step such as CMP is then performed to remove the excess dielectric layer. In some embodiments, a contact etch stop layer (CESL) is formed after the step of forming the strained layers 21 and before the step of forming the dielectric layer 23, and the CESL includes SiN, SiC or the like.

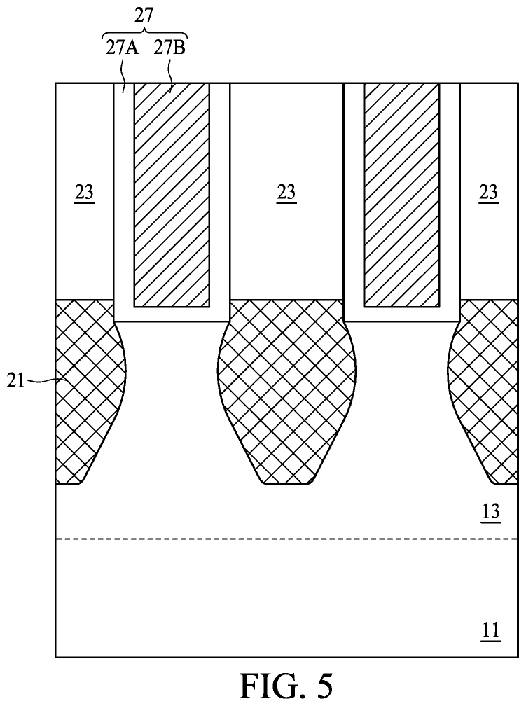

FIG. 5 is a cross-sectional view of intermediate stages following FIG. 4 in the formation of the memory structure 100, gate stacks 27 are then formed in the gate trenches 25. In some embodiments, the method of forming the gate stacks 27 includes forming a stacked layer with CVD, PVD, plating, or a suitable process, and then performing a CMP process to remove the stacked layer outside of the gate trenches. In some embodiments, the top surface of the dielectric layer 23 is substantially level with the top surfaces of the gate stacks 27. In some embodiments, the shape, profile and width of the gate stacks 27 are substantially similar to the shape, profile and width of the patterns 15.

In some embodiments, each of the gate stacks 27 includes a gate dielectric layer 27A and a gate 27B serving a word line of the memory structure 100. In some embodiments, the gate stacks 27 extend in a direction different from (e.g., perpendicular to) the extending direction of the fins 13. In some embodiments, each of the gate dielectric layers 27A surrounds the sidewall and bottom of the corresponding gate 27B and on the top and sidewall of each fin 13, as shown in FIG. 5. In some embodiments, silicon oxide layers are formed between the fins 13 and the gate dielectric layers 27A.

In some embodiments, each of the gate dielectric layers 27A includes a high-k material having a dielectric constant greater than about 10. In some embodiments, the high-k material includes metal oxide, such as ZrO₂, Gd₂O, HfO₂, BaTiO₃, Al₂O₃, LaO₂, TiO₂, Ta₂O₅, Y₂O₃, STO, BTO, BaZrO, HfZrO, HfLaO, HfTaO, HfTiO, a combination thereof, or a suitable material. In alternative embodiments, each of the gate dielectric layers 27A can optionally include a silicate such as HfSiO, LaSiO, AlSiO, a combination thereof, or a suitable material.

In some embodiments, each of the gates 27B includes a metal material suitable for forming a metal gate or portion thereof. In some embodiments, each of the gates 27B includes a work function metal layer and a fill metal layer on the work function metal layer. The work function metal layer is an N-type work function metal layer or a P-type work function metal layer. In some embodiments, the N-type work function metal layer includes TiAl, TiAlN, or TaCN, conductive metal oxide, and/or a suitable material. In alternative embodiments, the P-type work function metal layer includes TiN, WN, TaN, conductive metal oxide, and/or a suitable material. The fill metal layer includes copper, aluminum, tungsten, or a suitable material. In some embodiments, each of the gates 27B can further include a liner layer, an interface layer, a seed layer, an adhesion layer, a barrier layer, a combination thereof or the like.

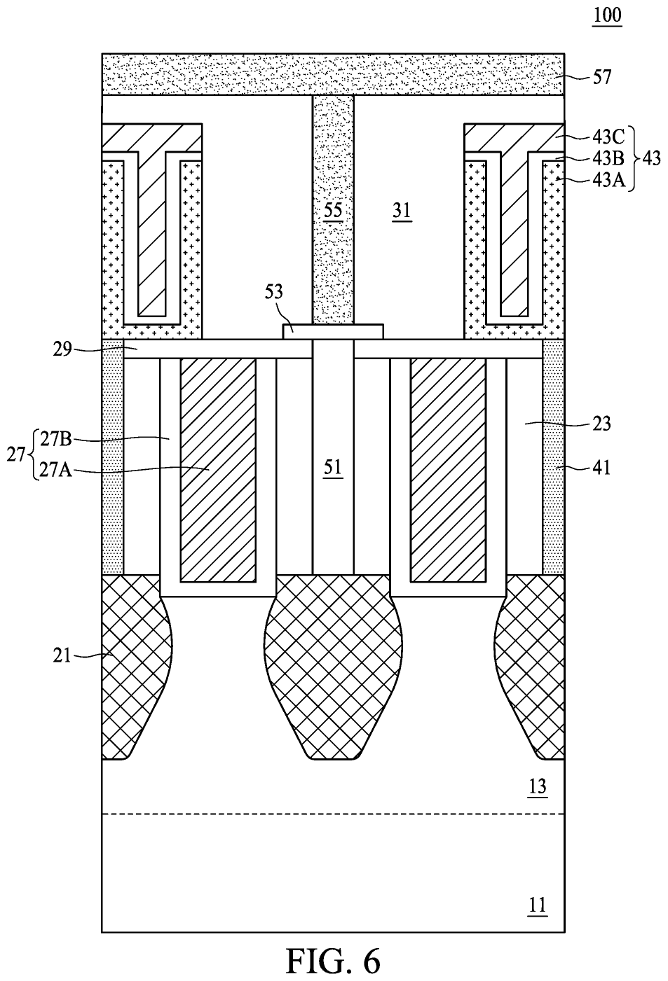

Referring to FIG. 6, a dielectric 29 and an interlevel dielectric (ILD) layer 31 are formed by deposition processes, and a bit line contact structure are then formed to electrically connect one of the strained layers 21 to a bit line 57. In some embodiments, the bit line contact structure includes a first contact 51 in the dielectric layer 23, a second contact 55 in the ILD layer 31, and a landing pad 53 between the first contact 51 and the second contact 55. In some embodiments, a capacitor contact 41 is formed in the dielectric layer 23 and electrically connects one of the strained layers 21 to a capacitor 43. In some embodiments, the capacitor 43 includes a bottom electrode 43A, an upper electrode 43C and a dielectric layer 43B between the bottom electrode 43A and the upper electrode 43C.

One aspect of the present disclosure provides a memory structure, including a substrate having at least one fin; a gate stack across the at least one fin; a first strained layer disposed at a first side of the gate; a second strained layer disposed at a second side of the gate; a bit line contact structure electrically connected to the first strained layer; and a capacitor contact electrically connected to the second strained layer.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A memory structure, comprising:
a substrate having at least one fin;
a gate stack across the at least one fin;
a first strained layer disposed at a first side of the gate;
a second strained layer disposed at a second side of the gate;
a bit line contact structure electrically connected to the first strained layer; and
a capacitor contact electrically connected to the second strained layer.

2. The memory structure of claim 1, wherein the first strained layer has a lower part below the substrate and an upper part above the substrate, and a sidewall of the lower part of the strained layer has a smoothly curved profile.

3. The memory structure of claim 1, further comprising a bit line electrically connected to the first strained layer via the bit line contact structure.

4. The memory structure of claim 3, wherein the bit line contact structure comprises a first contact, a second contact, and a landing pad between the first contact and the second contact.

5. The memory structure of claim 1, further comprising a capacitor electrically connected to the second strained layer via the capacitor contact.

6. The memory structure of claim 1, further comprising a bottom electrode, an upper electrode and a dielectric layer between the bottom electrode and the upper electrode.

7. The memory structure of claim 1, wherein the gate stack comprises a gate and a dielectric layer between the at least one fin and the gate.

8. The memory structure of claim 1, further comprising silicide layers on the first strained layer and second strained layer.

9. The memory structure of claim 1, wherein the first strained layer includes silicon germanium

10. The memory structure of claim 1, wherein the first strained layer includes silicon carbon or silicon phosphate.
